(19) United States
(12) Patent Application Publication
(10) Pub. No.: US 2005/0046016 A1
(43) Pub. Date: Mar. 3, 2005

(54) Electronic package with insert conductor array

(76) Inventor: Ken Gilleo, Cranston, RI (US)

Correspondence Address: MINTZ, LEVIN, COHN, FERRIS, GLOVSKY;AND POPEO, P.C., ONE FINANCIAL CENTER, BOSTON, MA, 02111, US

(21) Appl. No.: 10/930,370

(22) Filed: Aug. 31, 2004

Related U.S. Application Data
(60) Provisional application No. 60/499,602, filed on Sep. 3, 2003.
(60) Provisional application No. 60/501,778, filed on Sep. 11, 2003.
(60) Provisional application No. 60/555,008, filed on Mar. 22, 2004.

(51) Int. Cl. H01L 23/02

(52) U.S. Cl. 257/713

(57) ABSTRACT

A package for an electronic component includes an enclosure that defines a cavity and electrically conductive bodies that extend through a dielectric substrate that forms at least a portion of at least one side of the enclosure, each of the conductive bodies offering accessible electrical contact surfaces on opposite sides of the dielectric substrate. The dielectric material in the enclosed can be partially or entirely formed via injection molding.

### RELATED APPLICATIONS

This application claims the benefit of the following: U.S. Provisional Application No. 60/499,602, filed Sep. 3, 2003; U.S. Provisional Application No. 60/501,778, filed Sep. 11, 2003; and U.S. Provisional Application No. 60/555,008, filed Mar. 22, 2004. The entire teachings of each of these patent applications are incorporated herein by reference.

### BACKGROUND

Electronic packages (containing computer chips and other electronic components) are bonded to printed wiring boards for electronic communication therewith. Electronic packages are provided in several different formats: feed-through packages 12 (FIGS. 1 and 2), surface-mount packages 14 (FIGS. 3 and 4) and ball grid arrays 16 (FIGS. 5 and 6), all of which encapsulate a chip are overmolded with plastic.

Both feed-through and surface mount packages include metal leads 18 embedded in and extending from an epoxy molding compound 20; a chip 22 is also embedded in the epoxy molding compound 20 and coupled with the metal leads 18 via wires 24. The epoxy molding compound 20 fully surrounds and contacts the chip 22. The feed-through package 12 illustrated in FIGS. 1 and 2 is a dual in-line package (DIP). It differs from the surface-mount package 14 of FIGS. 3 and 4 in that the leads 18 of the feed-through package 12 are straight, allowing them to pass through a printed wiring board, whereas the leads 20 of the surface-mount package 14 are bent, allowing them to be bonded onto a proximate side of a printed wiring board.

A ball-grid array 16, as illustrated in FIGS. 5 and 6, includes a chip carrier (or platform) 26 having solder balls 28 mounted on one side of the chip carrier 26 and having the chip 22, wires 24 and epoxy molding compound 20 on the other side of the chip carrier 26. The chip 22 is bonded to the carrier 26 via a layer of die paste 29. Like the feed-through package 12 and surface-mount package 14, the ball-grid array 16 typically is overmolded with the epoxy molding compound 20, thereby leaving no cavity or free space around the encapsulated component (e.g., chip 22). Electronic communication between the chip 22 and the solder balls 28 is provided by copper patterns 30 on the surface of the chip carrier 26, which can be in the form of a polyimide substrate, and conductive vias 32 extending through the chip carrier 26.

Another form of electronic package is the “cavity package,” which is in the form of ceramic or metal cavity package having conductive connectors 34 protruding through the sides of a cavity-defining enclosure 36 (FIG. 7) or in the form of an injection molded plastic cavity 38 in a molded lead frame 40 (FIG. 8).

### SUMMARY

Described, infra, are new designs for packages suitable for containing electronic components. The packages include an enclosure that defines a cavity in which one or more electronic components (devices) can be mounted and a plurality of electrically conductive bodies (e.g., spheres) that extend through a dielectric substrate forming at least part of one side of the enclosure. Each of the conductive bodies has accessible (i.e., non-encapsulated) electrical contact surfaces on opposite sides of the dielectric substrate. The cavity-type package may be referred to as a cavity-up ball grid array (BGA), and it can contain electronic, optoelectronic (OE), MicroElectroMechanical Systems (MEMS) or MicroOptoElectroMechanical Systems (MOEMS) device(s).

The package can be made via a number of methods. According to one method, a sheet or film of dielectric material is fitted with an array of conductors that remain independent (electrically-isolated from one another) and protrude through both the top and bottom surfaces of the dielectric sheet. The resulting construction that now contains the firmly fixed array of conductors is insert-molded with a suitable thermoplastic resin, to form the base component of the cavity-type electronic package enclosure.

In accordance with another method, electrically conductive spheres, alone, are placed in a mold cavity suitable for use in an injection-molding machine. The molding tool cavity can have recesses for holding the spheres in place. The mold is closed and molten resin is injected into the cavity so that the spheres are trapped by the resin but remain exposed on both top and bottom. The resulting piece again is a plastic cavity-shaped part suitable for electronic packaging, having conductive spheres protruding from the bottom and through the inside.

At least one electronic component is mounted to the base component, which includes the dielectric substrate and conductive bodies, and electrical connections are made to the conductive spheres by wire bonding or direct attachment, also known as flip chip assembly. After the component(s) is/are attached and connected, a lid is sealed to the top of the base component by any known means suitable for plastics, such as adhesive bonding, ultrasonic sealing, or laser sealing. The sidewalls of the package can either be part of the base component or part of the lid (e.g., where the base component consists only of a planar dielectric substrate and conductive bodies passing there through). The completed package can be attached to a circuit board or subassembly by ordinary solder assembly or by clamping into a commercially available socket.

Where spheres (i.e., substantially spherical shapes) are used as the conductive bodies, the spheres can be shaped to produce flat contact surfaces, flanges or other shapes, as may be desired, depending upon the nature of the contacts and the methods of bonding therewith and other factors. Using coining methods, described herein, the exposed surfaces of the conductive bodies are formed into a variety of different shapes.

The methods and apparatus described herein, with connectors that protrude through the plastic package body, provide a standard surface mount technology (SMT) format that permits rapid automatic assembly and does not require secondary processing or additional hardware, like a flex connector.

The methods and apparatus of this disclosure offer a variety of advantages over the prior art. Methods described herein enable fabrication of a very-low-cost BGA cavity package that is suitable for general electronics, but also for MEMS, MOEMS and OE systems. Conventional overmolding cannot be used for mechanical and optical devices where free space (and an optical path for optical devices) is required. Packages described herein provide free space (i.e., or an air cavity) and also an optical path, if required. A lid formed of glass or other transparent material is attached to the plastic-molded base component of the package when an optical path is required, such as for MOEMS and for other optical products including displays. The thermoplastic nature of the housing permits the molding, as well as fabrication after molding, of ports or other access points for optical fiber, fluid lines, gas entry, etc.

The package style, known as an area array, is the most modem type, providing high-density efficiency and excellent electrical characteristics. The materials used in forming the package are of low environmental impact with no halogens and no lead. This packaging process, which produces a simple construction, produces no waste; and the materials are readily recycled, unlike present designs that are made with thermoset resins. The ability to use thin printed circuitry as an insert in the package can also provide very high density both for the package area array and for the chip bonding regions, which can be for multiple chips.

Fabrication can be carried out at very low cost with the injection molding techniques since no package circuit board, specialty substrate, or complex lead frames need be used. Furthermore, the ball pattern can be varied by changing a tool insert that holds the balls in place in the mold. Consequently, one mold can be used to produce several BGA “footprints.” The result is low tooling cost and fast changeover or turn-around resulting in faster time-to-market. Furthermore, there is no plastic waste since any scrap can be reused as thermoplastic regrind, unlike thermoset molding where scrap runners, and such, are not reusable and may be classified as hazardous waste, especially today's standard molding compounds that contain bromine.

The use of symmetrical spheres instead of posts or complex arrays simplifies the use of robotic handling equipment and total automation. The resulting product need not contain any of the hazardous materials, such as halogens and lead metal, now found in packages. The package can also be tested, burned in, and plugged into a socket instead of soldering. The ability to connect the package to the circuit board by means of a socket allows field repair and easy upgrade.

Additional advantages are offered by the coining procedures, described herein, for shaping the conductive bodies. First, flattening of conductive spheres protruding within the package provides a large area for wire bonding or for other attachment methods. Flattening also provides a more level topology that will make bonding easier and higher in yield. Reshaping the bottom of the sphere that protrudes through the underside of the package also has utility—a flat surface may be useful for some types of assembly and also for testing. Further still, forming flanges at both the inside and outside package junctions can improve the seal. The conical, or pin-like shape for the bottom protrusions can be suitable for a pluggable interconnect. This design is analogous to a pin grid array that normally requires preformed pins to be inserted.

### BRIEF DESCRIPTION OF THE DRAWINGS

In the accompanying drawings, described below, like reference characters refer to the same or similar parts throughout the different views. The drawings are not necessarily to scale, emphasis instead being placed upon illustrating particular principles of the methods and apparatus characterized in the Detailed Description.

FIG. 1 is a perspective view of a dual in-line package.

FIG. 2 is a sectional view of the dual in-line package.

FIG. 3 is a sectional view of a quad surface-mount package.

FIG. 4 is a perspective view of the quad surface-mount package.

FIG. 5 is a perspective, cut-away view of a ball-grid-array package.

FIG. 6 is a sectional view of the ball-grid-array package.

FIG. 7 is a top-side view of a metal cavity package.

FIG. 8 is a perspective view of a molded lead frame and an injection molded plastic cavity.

FIG. 9 is a side view of the flex circuit after a lid is sealed to the flex circuit.

FIG. 10 is a sectional side view showing the insertion of conductive spheres into a dielectric substrate in forming a flex circuit.

FIG. 11 is a sectional side view of the dielectric substrate with conductive spheres inserted therein.

FIG. 12 is a top view of the dielectric substrate with conductive spheres inserted therein.

FIG. 13 is a sectional side view of a dielectric substrate similar to that of FIG. 11, except with conductive posts/rivets inserted instead of spheres.

FIG. 14 is a top view of flexible circuit pattern on a dielectric substrate.

FIG. 15 shows holes punched through the circuit pattern and substrate and a conductive sphere being inserted into one of the punched holes.

FIG. 16 shows the insert with conductive spheres inserted into each of the punched holes.

FIG. 17 is a top view of a dielectric substrate having channels that expose a catalyst on one surface and embedded conductive spheres.

FIG. 18 is a sectional side view showing the substrate of FIG. 20 immersed in a plating bath.

FIG. 19 shows the substrate after a conductive layer is plated in the channels while immersed in the plating bath.

FIG. 20 is a side view of the substrate after plating.

FIG. 21 is a sectional side view showing the base component of a package formed after injection molding thermoplastic material around a flexible circuit including conductive spheres.

FIG. 22 is a sectional side view showing the base component of a package formed after injection molding thermoplastic material around a flexible circuit including conductive posts/rivets.

FIG. 23 is a sectional side view showing the base component of a package formed after injection molding thermoplastic material around a flexible circuit including a conductive pattern punched through the substrate.

FIG. 24 is a sectional side view showing the package bonded with solder balls and having an electronic component contained in the package and a lid sealing the package.

FIG. 25 is a side view showing a package, wherein the lid is a dielectric insert that also includes conductive spheres and an electronic component such that electronic components are electrically accessible via opposite sides of the package.

FIG. 26 is a view of the molding surface of the top section of a mold.

FIG. 27 is a view of the molding surface of the bottom section of the mold.

FIG. 28 is a sectional side view of the mold.

FIG. 29 illustrates the mold closed with conductive spheres inserted.

FIG. 30 illustrates the mold closed with polymer injection molded around the conductive spheres.

FIG. 31 is a perspective view of the injection-molded base component.

FIG. 32 is a sectional side view of the injection-molded package with a single device and a lid.

FIG. 33 is a sectional side view of the base component of a package where inner surfaces of the conductive spheres are coined flat and flush to the inner surface of the package.

FIG. 34 is a sectional side view of the base component of a package where outer surfaces of the conductive spheres are coined flat.

FIG. 35 is a sectional side view of the base component of a package where the inner surfaces of the conductive spheres are coined, and the inner and outer surfaces of the conductive spheres are flanged.

FIG. 36 is a sectional side view of the base component of a package where the conductive bodies are coined to form a pluggable shape.

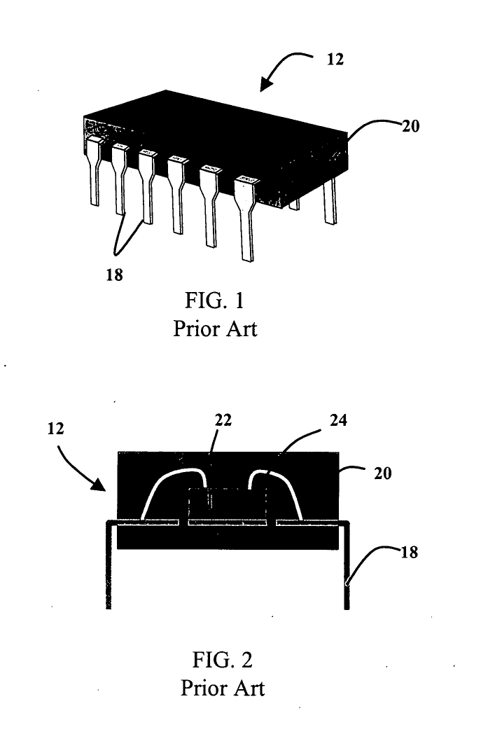

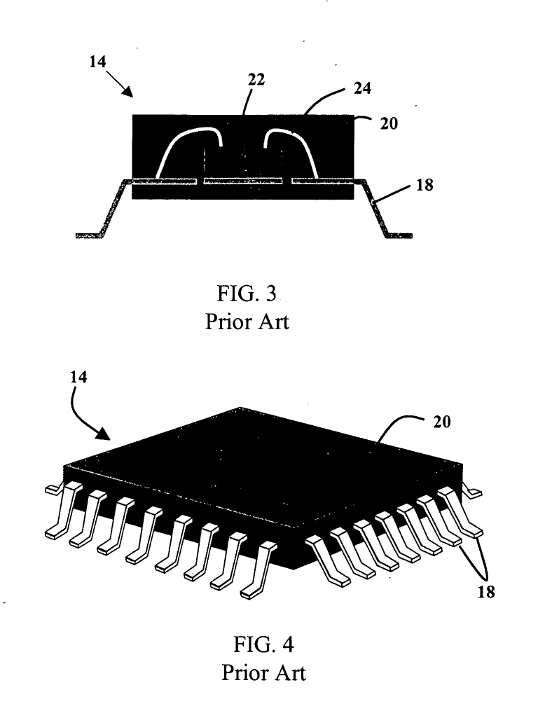

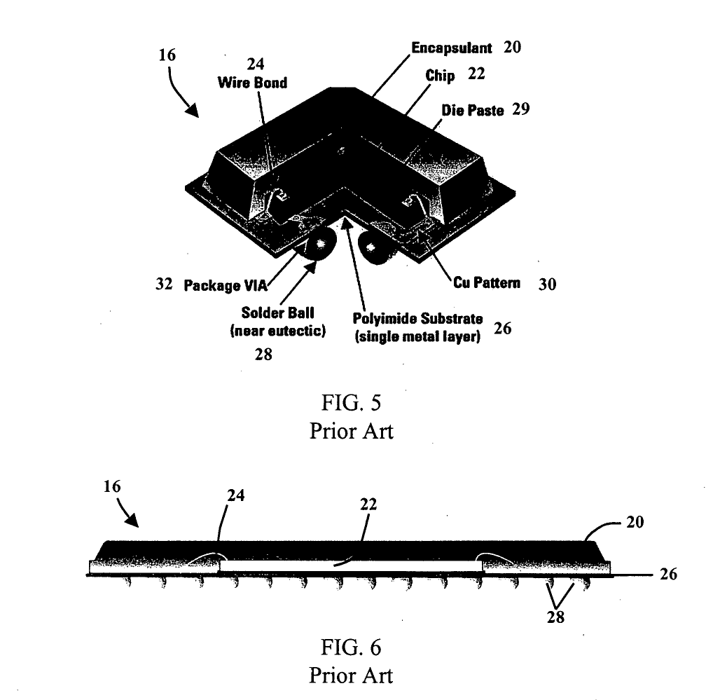

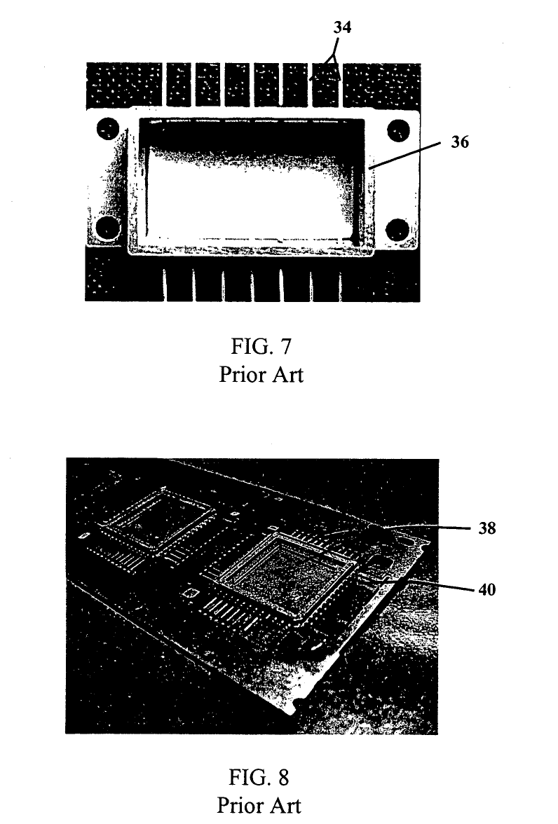

### DETAILED DESCRIPTION

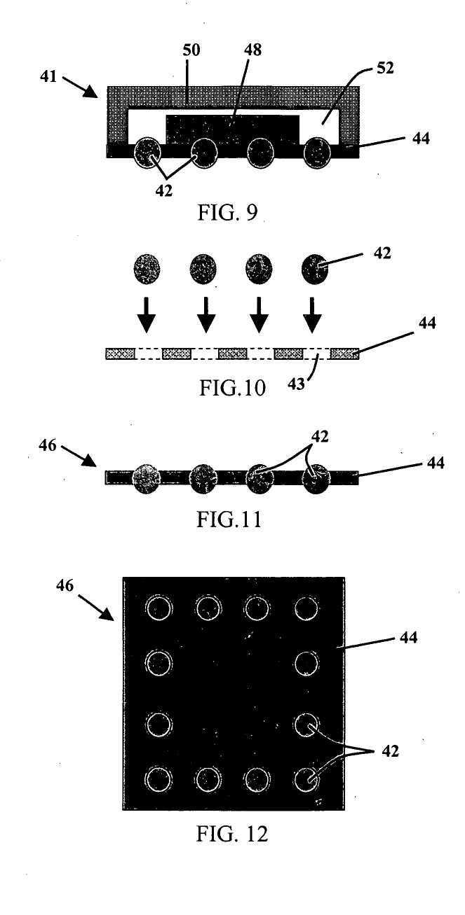

A package for containing one or more electronic components is illustrated in FIG. 9. The package 41 includes a dielectric substrate 44 having conductive bodies 42 penetrating there through. An electronic component 48 is bonded to the top surface of the dielectric substrate 44 and electrically coupled with the conductive bodies 42. The package 41 is completed when a lid 50 is added to fully define and seal the cavity 52 formed by the package 41.

According to one method, shown in FIGS. 10-12, an array of conductive bodies 42 (e.g., in the form of spheres) is inserted into orifices 43 defined by a pre-formed planar dielectric substrate 44 (e.g., in the form of a sheet or film formed of a plastic). The plastic of which the substrate 44 is formed can be similar to or different from the molding resin that is used to form the rest of the package via injection molding. The substrate 44 and conductive bodies 42 together form an “insert” 46.

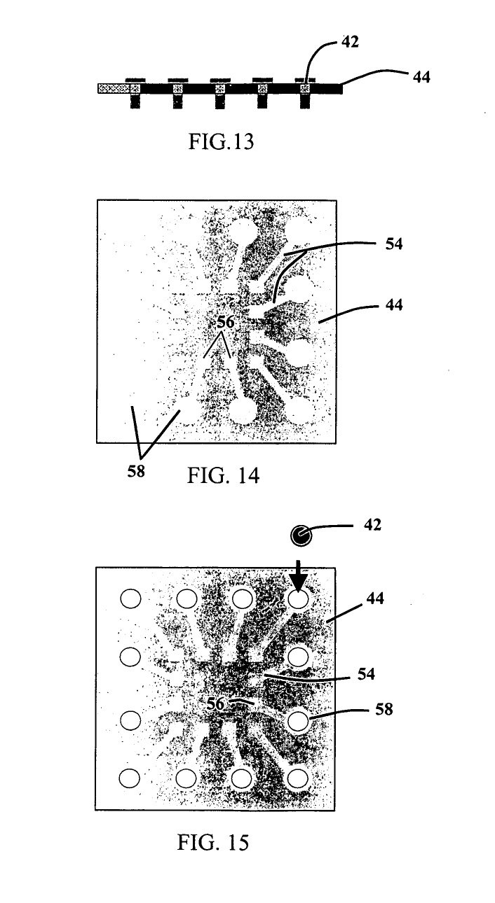

The simplest configuration for the insert 46 is a flat piece of plastic 44 with electrically conductive bodies 42 embedded and protruding through both the top and bottom surfaces as shown in FIG. 11. The conductive bodies 42 can be solid metal, such as copper or nickel, or coated metal including solder alloys. The conductive bodies 42 can also be formed of a polymer composite, such as metal-filled polymer (conductive adhesive). The conductive bodies 42 can also be inorganic, such as a ceramic that is coated with a conductor, especially metal. In particular embodiments, the conductive bodies 42 do not significantly deform during the insert-molding process or in subsequent assembly of the resulting package to a printed circuit board. When conductive polymer composites are used, the assembly process should be compatible; e.g., conductive adhesive paste can be used to assemble packages to printed circuit boards at lower temperatures than metallurgical soldering. While spheres are highly suitable as a consequence of their ease of manufacturing and handling, posts, rivets, and other shapes are useful. An embodiment in which the conductive bodies 42 are in the form of rivets is illustrated in FIG. 13; the assembly process for rivets and other shapes is essentially the same as for the embodiments where spheres are used.

A suitable resin from which the package can be fabricated is from the liquid crystal polymer (LCP) class, such as the Vectra™ resin (from Ticona/Celanese of Summit, N.J., USA). However, other high-temperature engineered plastics can also work. The substrate 44 is a good dielectric, such as plastic, glass or other ceramic. In one embodiment, the dielectric substrate is formed of polyester. Alternatively, the dielectric substrate can be a green ceramic, into which the spheres are placed; and the green ceramic is then fired.

The conductive bodies 42 can be made of metal, metal alloys, metal-filled plastics (conductive plastics) or intrinsically conductive polymers. In particular embodiments, the conductor material is a high-melting-point metal, such as copper or nickel, that can be soldered during a later assembly step. A low-melting metal or alloy is undesirable in many embodiments since it would melt during molding or solder assembly. The conductive body 42 can have a thin coating of solder on it. The conductive body 42 can also/alternatively be plated with a metal to prevent corrosion or to enhance bonding. Gold, for example, can be plated onto conductive bodies formed of nickel so that the conductive bodies 42 can be wire bonded. Copper conductive bodies can be plated with nickel, followed by gold, a common sequence in electronics.

The conductive bodies 42 can be assembled to the dielectric substrate 44 in a number of ways. These include first forming slightly undersized holes in the dielectric substrate 44 and then forcing the conductive bodies 42 into the holes. The conductive bodies 42 should remain intact so that the insert 46 can be placed into an injection mold, but conductive bodies 42 do not need to be sealed and bonded to the dielectric substrate 44 since the sealing can occur during the molding step. The conductive bodies 42 can also be pressed through a suitable dielectric substrate using sufficient force and proper tooling, such as via use of a base plate with a pattern corresponding to the size and shape of the spheres or other conductive-body geometry. Heat can be applied in this conductor-inserting process to soften the substrate 44 if it is made from a thermoplastic. Nail-like conductive bodies that can easily pierce the dielectric substrate can also be used.

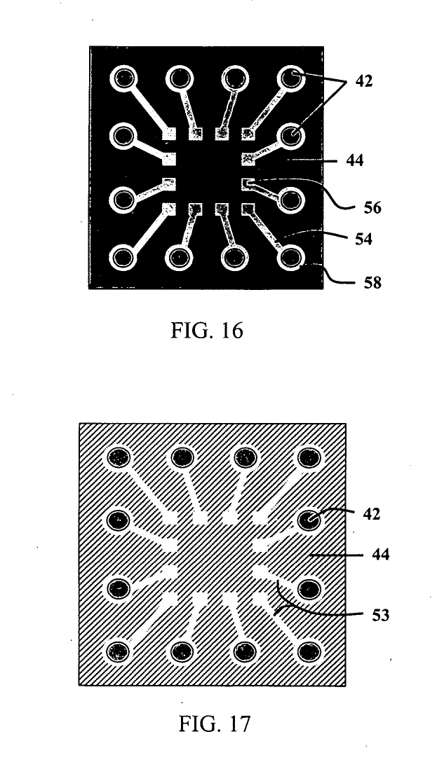

The dielectric substrate 44 can also have electrically conductive paths, such as a flexible printed circuit, printed on its interior surface. The electrical pathway pattern 54 (FIG. 14) provide conductive links between the conductive bodies and electrical contact pads 56 that are conductively bonded with electrical contacts on an electronic component via chip wire bonding or direct chip attach. A continuous roll process can be used for dielectric substrates with no conductive pattern, and for flexible circuit substrates that have long been produced in rolls or in reel format. The pads 58 and underlying dielectric material are punched out, and the conductive bodies 42 are inserted into the resulting orifice, as shown in FIG. 15. The resulting insert is shown in FIG. 16.

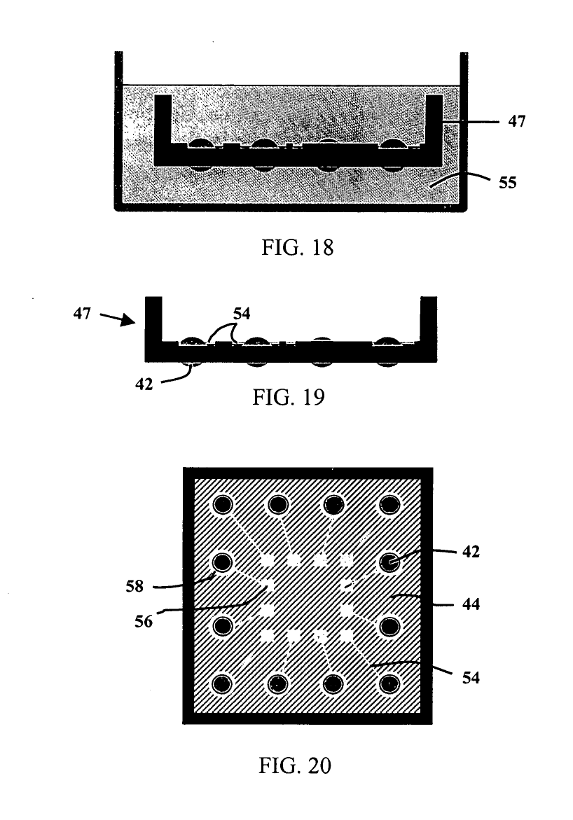

The conductive paths 54 can also be formed by plating. The molding tool can create channels 53 in the dielectric substrate 44 (see FIG. 17). The channels 53 expose a plating catalyst contained in the substrate 44. After embedding the insert 46 in an injection-molded structure to form a base component 47 of the package (discussed, below), the insert 46 is then immersed in a plating solution 55 (FIG. 18) that is catalyzed by the catalytic surface to plate a layer of, e.g., copper to form the conductive paths 54, including pads 56 and 58 (FIGS. 19 and 20).

The insert 46 can also be formed by methods other than by inserting the conductive bodies 42. For example, metal posts can be formed on the bottom half of a printed circuit by methods such as plating, where a single-sided flexible circuit can be the starting point for making an insert with posts by the following steps. First, holes are formed in the dielectric substrate under pads laid out in an array of the desired posts in a process referred to as “back-baring,” which produces “double access” flex. The flex circuit is next masked on top to prevent plating of the circuit traces. The bottom side can also be masked but openings are left around the holes under the pads. The part is then plated with suitable metal, such as copper, to form posts of a desired length in the holes. The masks are then removed, or stripped, to produce an insert wherein the plated metal extends through the dielectric substrate to form the conductive body.

Conductive bodies can also formed by producing dimples in a flexible circuit. The dimpling process, which has been used to make reconnectable flex circuits, involves pressing the circuit in a match tool set with, or without, heat depending on the material. The conductive material is thereby pushed through the substrate to provide a conductive link extending through the substrate to the opposite side of the substrate where it forms an electrical contact.

Conductive bodies can also be formed by punching out the dielectric around a conductor pattern on three sides at a pad 58 (see FIG. 14), leaving the side proximate to the strip of conductive material extending between pads 56 and 58 intact to make a tab that can be bent out of plane so as to extend through the hole that was punched out of the dielectric substrate 44 and to thereby be accessible on the other side of the dielectric substrate. The cutting and forming can be performed in one step with or without heat, depending on the dielectric material.

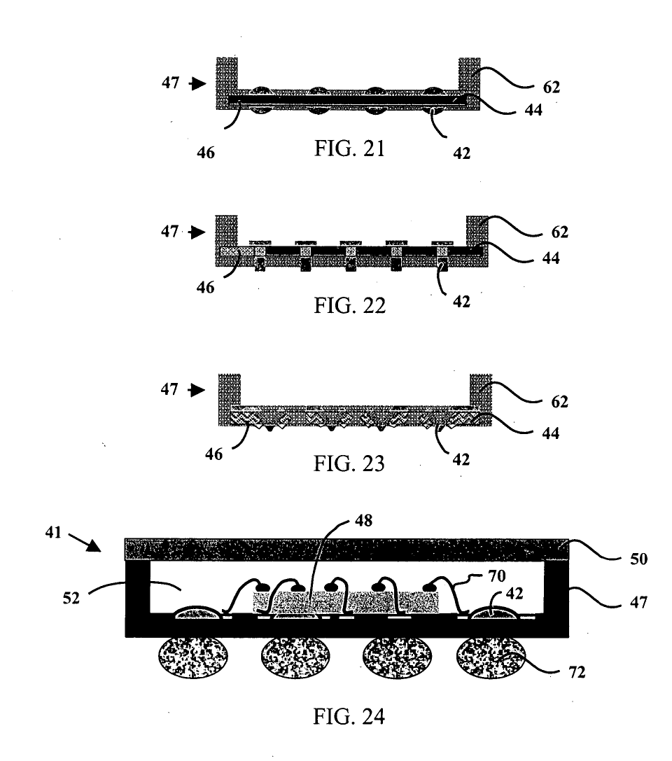

The next step involves insert molding any of the inserts 46 made by the processes just described or by other methods that will become apparent to one skilled in the art of circuitry and interconnects. The insert 46 is placed into a molding tool 60, including top 66 and bottom 68 sections (FIGS. 26-28); the mold 60 is closed and melted resin is injected. The injected resin (e.g., LCP resin) can have a melting point that is lower than the resin (e.g., polyester) from which the insert is formed. The solidified base component 47 (see FIG. 21-23) is ejected from the mold in a predetermined cycle. The insert-molding process can be performed automatically and with multiple cavity molds for very low-cost and high throughput. The resulting base component 47 is shown in FIGS. 21-23 using several of the types of inserts 46 described, wherein the insert 46 is embedded into the injection-molded portion 62 of the base component 47. The molds 60 can have recesses 64 to accommodate the conductive bodies 42 that protrude through the dielectric substrate 44.

The base component 47 is now ready to receive one or more electronic components 48. At least one electronic, optical, mechanical, or combinational device (collectively referred to as “electronic components”), including MEMS and MOEMS, is attached to the inside of the cavity defined by the base component 47 with die-attach adhesive. The electronic component 48 is then connected to the protruding conductive bodies 42, or to pads 56 (see FIG. 16) on the printed circuit depending on the construction of the insert 46 that is used. This connection can be provided by wire 70 bonding, the most common chip connection method for packaging. The conductive bodies 42 or circuit pads 56 should have a finish suitable for wire bonding. Several finishes permit wire 70 bonding, as shown in FIG. 24; but the most common is high-purity gold. The wire-bonding surfaces can be made of copper that is plated with nickel and then gold or palladium. Silver and platinum have also been used as wire-bondable surfaces when the bonding wires are made of gold. More recently, and with the advent of copper metallization for ICs, copper-wire bonding has been introduced. The integrated-circuit pads have a copper finish but may require oxide removal. When copper-wire bonding is used with this package, the conductive bodies 42 can be made of copper. The copper can have an anti-corrosive coating or treatment. The use of copper wire 70 and copper conductive bodies 42 or copper pads 56 provides a simple and low-cost version of this package 41.

The final step is lid closure, or lid sealing. A lid 50 made of plastic, metal, glass, other ceramic, or any strong material that serves as a barrier, can be applied to the top of the base component 47. The lid 50 can be sealed using adhesives for all materials. Direct heat, laser energy, ultrasonic bonding, or any other common methods also can seal plastic lids. A glass lid is especially useful for optoelectronic devices, including MOEMS, exemplified by micro-mirror arrays used in digital projectors and optical switches. The glass lid can be bonded by adhesives, such as epoxies. The glass lid can also be sealed by infrared, or near-infrared laser energy. Glass is mostly transparent to these wavelengths allowing the beam to interact with the plastic housing. Addition of a small amount of carbon black, commonly added to plastics, to the base component 47 will cause photon absorption and heating. The laser sealing is especially useful when heating of the electronic component 48 should be avoided. After lid sealing, the package 41 can be tested and shipped. The conductive bodies 42, when made of copper or nickel, allow simple plug-in testing and burn-in.

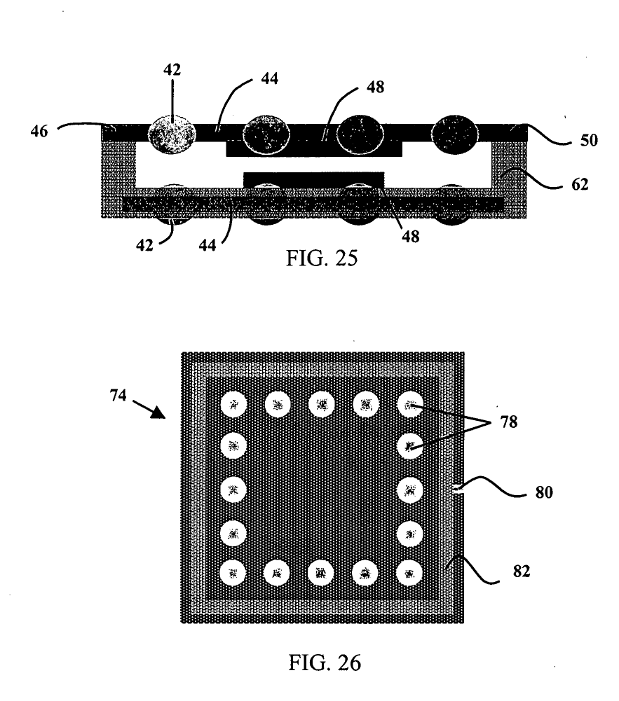

The lid 50 can also include an insert 46 or can otherwise incorporate conductive bodies 42 that pass through the lid 50 to thereby provide conductive bodies 42 on opposite sides of the package 41, as show in FIG. 25. Accordingly, electronic components 48 can be coupled with the conductive bodies 42 within the package 41 on both sides of the cavity 52. The electronic components 42 on opposite sides of the package 41 can be different, enabling the package 41 to be flipped around and reconnected to serve dual purposes, depending on what functions are needed. The two-sided connections also enable use of two different systems using a clamping socket.

The cavity 52 can optionally be filled with a liquid fluid prior to sealing the lid 50. The fluid is electrically insulating and non-corrosive. The fluid can act as a cooling agent (or heat dissipation medium) and can also exclude moisture. When fluid is added prior to lid sealing, the lid 50 can be sealed by localized heating (e.g., by a laser) so as not to evaporate the fluid or cause degradation. Fluid can also be added after the lid 50 is attached, which can be an advantageous approach for measuring devices, such as bio-MEMS chips. The mold design can include one or more fluid or gas ports to provide the package 41 with a passage for filling the cavity 52 after lid placement. As an alternative to liquid fluid, the cavity 52 can be filled with a gas, gel, powder or other solid.

After the lid 50 is sealed onto the base component 47 of the package, the finished package 41 is ready for standard assembly to printed circuit boards by solder or adhesive, or for plugging into a socket (pressure clamp type). A package 41 bonded to solder balls 72 is illustrated in FIG. 24. The solder balls 72 are also soldered to contacts on a printed circuit board.

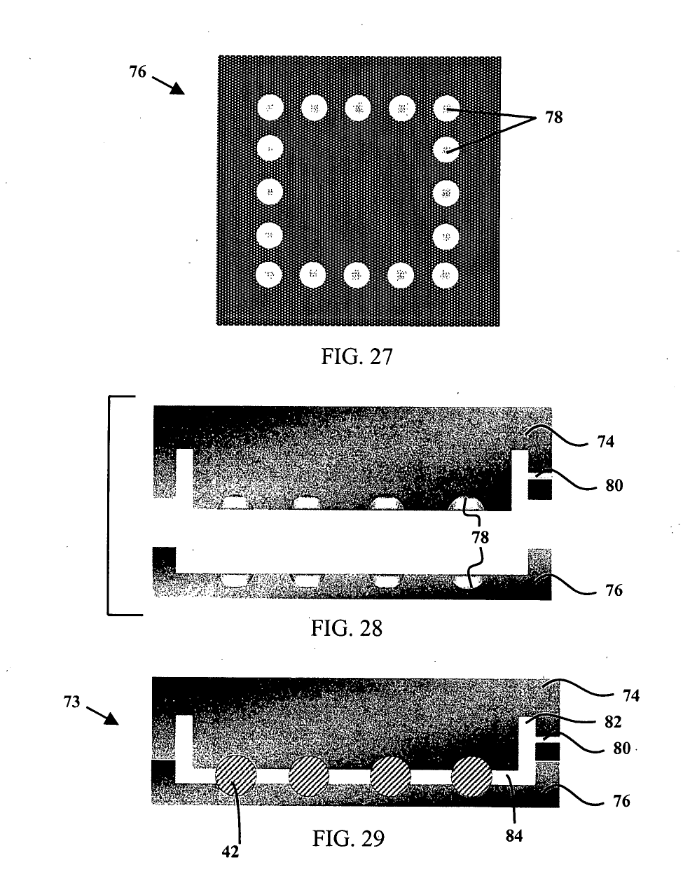

In an alternative method for package fabrication, which does not employ the insert of the above-described methods, electrically conductive spheres are placed into a mold cavity suitable for use in an injection-molding machine. The top 74 and bottom 76 sections of the mold 73 are illustrated in FIGS. 26 and 27, respectively. The mold 73 can have concave recesses 78 in sections 74 and 76 to accommodate the conductive spheres 42, or a mold insert with said recesses 78 can be placed in the mold to allow for rapid change in the number of spheres 42 with the same plastic package configuration. FIG. 28 provides a side view of the mold, further illustrating a passage 80 in the top section 74 for filling the mold cavity with injected resin. In the illustrated embodiment of the mold, the top section 74 defines a cavity 82 for forming the sidewalls of the package, while the two mold sections 74 and 76 together define the cavity 84 for forming the base of the package. The mold design can also ports for fiber-optic fiber or other photonic transmission media. Each port can be molded as plastic or insert-molded as a ceramic ferrule.

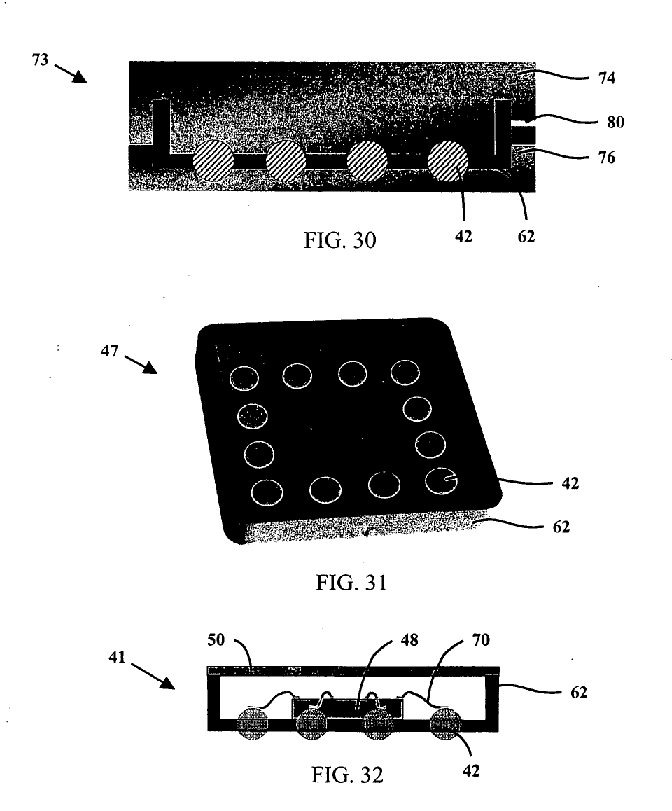

Conductive bodies 42, in the form of spheres, are placed into the mold prior to molding as shown in FIG. 29. The spheres should not melt or deform during injection molding, nor melt during subsequent solder assembly of the package to a printed circuit board. FIG. 30 shows the closed mold 73 with spheres 42 and plastic resin 62 injected into the mold, which is still closed. FIG. 31 shows the resulting finished base component 47 of the package after removal from the mold 73.

A suitable resin for molding around the conductive bodies 42 and creating the base component 47 of the package 41 is a high-melting plastic that will not be damaged or deformed during solder assembly or during actual use. A particularly suitable resin is from the liquid crystal polymer (LCP) class such as Vectra™ LCP (Ticona, Inc./Celanese AG). However, also suitable for the injection molding are other engineered plastics that have high deformation temperatures, high strength and good gas barrier properties when conventional solder assembly is used.

Lower-melting plastics (less than 200° C.) can be used to form the package where lower-melting solders or conductive adhesives for assembly to the circuit board are used. Conductive adhesives can be used for assembly at temperatures under 150° C., and as low as 100° C., thus making it possible to use lower-cost plastic resins.

The conductive bodies 42 can be coated with organic materials such as organic solderability preservatives (OSP), rosin, dry flux, or primers that can help improve the seal between the sphere and plastic. These materials should either be compatible with soldering and bonding or be easy to remove. OSPs are available that are removed by the heat of solder assembly, for example.

The conductive bodies 42 again can be copper or nickel, with a finish suitable for wire bonding. FIG. 32 shows the package 41 with an attached die, or chip, that is connected by wire bonding. Several finishes permit wire bonding, but the most common is high purity gold. The spheres can be nickel with a gold plating finish, or copper with a nickel barrier and a final gold or palladium plate. Silver or platinum can also be used as wire-bondable surfaces, particularly when the bonding wires are made of gold. More recently, and with the advent of copper metallization for ICs, copper wire bonding has been introduced. The IC pads have a copper finish but may require oxide removal. When copper wire bonding is used with this package, the spheres can be made of copper. The copper can have an anti-corrosive coating or treatment.

Since gold metal, used to facilitate wire bonding, can interfere with soldering by forming intermetallic compounds, this finish can be applied after the part has been molded. This would permit gold plating on the spheres that protrude from the inside of the package and leave the bottom sections free of gold for soldering. Gold plating solution can be added to the package cavity to permit gold plating on the exposed conductive spheres. Gold can be plated via electroless plating, though electrolytic plating can be accomplished by applying current to the protruding bumps on the bottom of the package. Such a process can be easily automated.

The electronic component(s) and lid can then be added, the lid sealed, and the package bonded to a substrate, all as described for the previous methods.

The spheres can be held in place during molding by having curved recesses in the base of the molding tool. The top mold should also have recesses to accommodate and protect the spheres so that they will remain as accessible protrusions after molding. The recesses can be part of the mold or a mold insert. Both the top and bottom recesses can be coated with a material that will aid in sealing, protect the spheres from damage, repel molten plastic, and otherwise improve the molding quality. Such materials can be organic films, such as Teflon™ or silicone rubber. While a permanent material may be preferred, temporary coatings can also be used.

The tool can be magnetic so as to hold spheres made from paramagnetic metals such as nickel. A tooling insert can be placed in the mold to accommodate the spheres so that simply changing the tool insert can mold different patterns. The tool insert can also be a sacrificial and temporary system that is removed after the molded part is ejected from the mold. The spheres can be plated prior to molding to prevent corrosion or to improve bondability and solderability. The spheres can be treated prior to molding to enhance bonding to the molding plastic using plasma, arc discharge and other processes for cleaning and activating the surface that are well-known. Spheres can also be coated with a primer to enhance bonding to the plastic or to produce a hermetic seal. However, the primer cannot interfere with bonding or soldering, otherwise it must be removed after molding. The sphere shape can be slightly elliptical but a symmetrical sphere is preferred for ease of handling and for ease of sphere manufacture.

The conductive spheres can protrude from both the top (package interior) and bottom. However, the bottom part of the sphere can be flush with the plastic with access accomplished by skiving, or grind off some of the plastic. This will expose the conductive sphere that becomes planar in the process, and also remove any coating or plating. This is advantageous when the spheres are plated with gold for wire bonding and the gold on the bottom would interfere with soldering. Solder balls can be attached to the exposed conductive areas using well-established “balling processes” and equipment (FIG. 24 shows a package with solder balls attached). The result is a ready-to-assemble BGA package. Alternatively, conductive adhesive can be applied to the exposed “pads” as discrete bumps or as an anisotropic conductive adhesive film that is widely available.

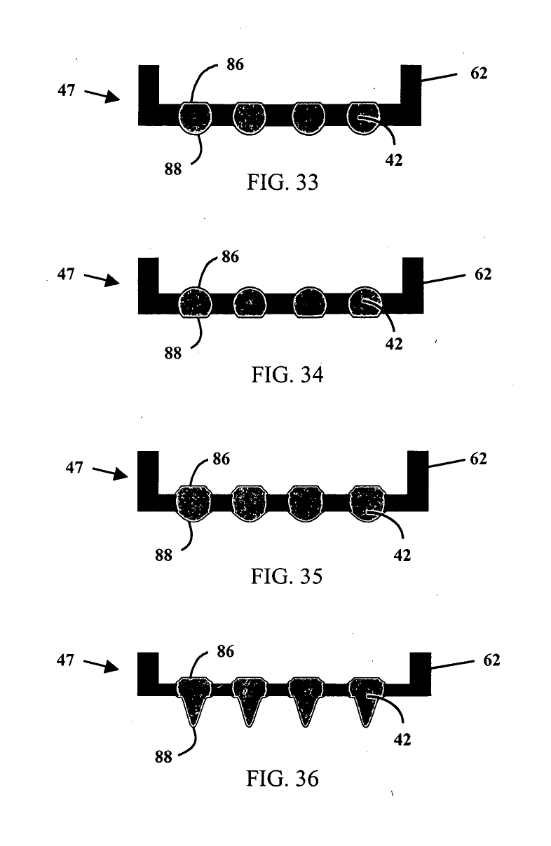

While a sphere may be the ideal shape for production of conductive bodies (molten metal forms spheres naturally) and for handling simplicity, other shapes may be preferred for the finished package. Conductive spheres can be shaped to produce flat contact surfaces (FIGS. 33-36), flanged surfaces (FIGS. 35 and 36), and cone-shaped surfaces (FIG. 36). The part of the conductive body 42 that protrudes within the package (i.e., the interior surface 86) can remain a curved surface (as in FIG. 34) for connection to the chip, or integrated circuit. A flat geometry for the interior surface 86 (as in FIG. 33) is more suitable for wire bonding and also increases seal integrity. The interior 86 and exterior 88 surfaces of the conductive bodies 42 can be flattened or shaped (coined) into any of a variety of other geometries. E.g., the curved surface of a sphere can be made flat (as the interior surface 86 is in FIG. 33 and as the exterior surface 88 is in FIG. 34) or conical for plug-in connection (as is the exterior surface 88 in FIG. 36). The sphere can also be shaped to form a flange to enhance sealing to the plastic body (as are the surfaces in FIGS. 35 and 36).

The shaping (coining) of the surfaces can occur during the injection-molding step (via the shape of the mold). Since the injection mold is made of a very-hard steel alloy, the mold is well-suited to serve as a coining tool. The conductive spheres are made of a metal that can be coined, such as copper. Tests have shown that copper spheres plated with nickel and then with palladium can be coined without damaging the finish.

The shape produced in FIG. 33, where only the interior surfaces 86 (i.e., the protrusions that extend into the package) of the balls 42 are coined, is obtained using a mold top section 74 (see FIG. 28) having either no concave recesses for the balls or having recesses 78 that are made very shallow to produce a flat surface 86. The exposed surfaces 86 and 88 of the spheres 42 will take on whatever shape is fabricated into the mold sections 74 and 76. Flanges can be formed using wide-and-shallow recesses that force the conductive material outward over the surface of the plastic/dielectric body. Injection molding machines exert tremendous clamping pressure (in the several tons range) and, therefore, are excellent coining presses.

If a conical shape for a plug-in design is desired, the mold bottom section 76 (see FIG. 28) is provided with recesses 78 having this conical shape. The volume of the conical recess should be sufficient to accommodate the conductive sphere 42 but should still be small enough to exert pressure on the conductive sphere to coin its exposed surface 88. The use of mold coining, or in-mold coining, saves on tooling and eliminates the need for an additional (separate) coining step. The mold is capable of shaping both the plastic of the dielectric substrate 44 and the conductive spheres 42.

Coining after molding can also be accomplished in the mold, especially when the interior surface 86 of the conductive body 42 is to be flattened. The mold is opened and a planar tool made of hard material (e.g., steel) is pressed against the interior surface 86 of the conductive body 42 protruding inside the package.

Alternatively or in addition, the surfaces 86 and 88 can be coined after the part is molded and ejected from the molding machine. The base component 47 is placed on a flat, hard surface and a planar platen that can fit into the cavity defined by the base component 47 is pressed against the protruding conductors. When both tool surfaces are flat, coining occurs at both the interior 86 and exterior 88 surfaces of the conductive bodies 42. Surfaces can be coined after injection molding using the bottom section 76 of the mold as the base tool and a simple mechanical arbor as the top tool. If the bottom tool has concave recesses that accommodate the protruding conductive bodies 42, then a flat top tool will coin the conductive bodies 42 on their interior surfaces 86 only.

In describing embodiments of the invention, specific terminology is used for the sake of clarity. For purposes of description, each specific term is intended to at least include all technical and functional equivalents that operate in a similar manner to accomplish a similar purpose. Additionally, in some instances where a particular embodiment of the invention includes a plurality of system elements or method steps, those elements or steps may be replaced with a single element or step; likewise, a single element or step may be replaced with a plurality of elements or steps that serve the same purpose. Moreover, while this invention has been shown and described with references to particular embodiments thereof, those skilled in the art will understand that various other changes in form and details may be made therein without departing from the scope of the invention. Finally, while various elements and steps are discussed in reference to a particular apparatus or method, those elements and steps can likewise be used in other alternative apparatus and methods discussed, above, unless they are in conflict therewith.

1. A package for an electronic component, the package comprising a plurality of electrically conductive bodies that extend through a dielectric substrate, each of the conductive bodies offering accessible electrical contact surfaces on opposite sides of the dielectric substrate.

2. The package of claim 1, comprising an enclosure that defines a cavity, the dielectric substrate forming at least a portion of at least one side of the enclosure.

3. The package of claim 2, further comprising at least one electronic component mounted within the cavity, the electronic component having electrical contacts that are electrically bonded to the conductive bodies, and the electronic component having exposed surfaces that do not contact the enclosure.

4. The package of claim 3, wherein the electronic component is selected from the group consisting of a semiconductor chip, an integrated circuit, an optoelectronic device, a microelectromechanical device, and a microoptoelectromechanical device.

5. The package of claim 3, wherein the electronic component is mounted to the enclosure only along the side of the electronic component that is facing the conductive bodies.

6. The package of claim 2, wherein the enclosure comprises a lid that forms at least one wall of the enclosure distinct from the dielectric substrate through which the conductive bodies extend.

7. The package of claim 6, wherein the lid comprises a second dielectric substrate, and wherein additional electrically conductive bodies extend through the second dielectric substrate.

8. The package of claim 6, wherein the lid is transparent to visible radiation.

9. The package of claim 6, wherein the lid is transparent to infrared radiation.

10. The package of claim 6, wherein the lid is transparent to ultraviolet radiation.

11. The package of claim 1, wherein the conductive bodies are substantially spherical.

12. The package of claim 1, wherein at least one accessible surface of one or more of the conductive bodies is flattened.

13. The package of claim 1, wherein at least one accessible surface of one or more of the conductive bodies has a substantially conical shape.

14. The package of claim 1, wherein at least one of the conductive bodies includes a flange formed around the dielectric substrate at an orifice through which the conductive body passes.

15. The package of claim 1, wherein the conductive bodies comprise one or more metals.

16. The package of claim 15, wherein the conductive bodies comprise a metal alloy.

17. The package of claim 15, wherein the conductive bodies comprise a metal-filled plastic.

18. The package of claim 15, wherein the conductive bodies comprise a metal-coated dielectric material.

19. The package of claim 18, wherein the metal-coated dielectric material is a metallized ceramic sphere.

20. The package of claim 2, wherein the enclosure comprises a plastic.

21. The package of claim 20, wherein the plastic is thermoplastic.

22. The package of claim 2, wherein the enclosure comprises a ceramic.

23. The package of claim 2, further comprising electrically conductive pathways formed on a side of the dielectric substrate facing into the cavity, wherein the electrically conductive pathways are electrically coupled with the conductive bodies extending through the dielectric substrate.

24. The package of claim 23, further comprising:
electrically conductive contact pads on the side of the dielectric substrate facing into the cavity, the contact pads being electrically coupled with the electrically conductive pathways; and
at least one electronic component mounted within the cavity, the electronic component having electrical contacts that are electrically coupled with the contact pads on the dielectric substrate.

25. A method for packaging an electronic component comprising:
providing a base component including a dielectric substrate, the dielectric substrate having a plurality of conductive bodies extending therethrough;
mounting an electronic component to the base component and coupling electrical contacts on the electronic component with the conductive bodies; and
mounting a lid on the base component to form an enclosure that defines a cavity in which the electronic component is contained.

26. The method of claim 25, wherein each of the conductive bodies has an outer surface that is exposed outside the cavity and an inner surface that is exposed inside the cavity, the method further comprising attaching outer surfaces of the conductive bodies to electrical contacts on a printed circuit board.

27. The method of claim 25, further comprising filling the cavity with a dielectric fluid or with a dielectric gel after the electronic component is mounted therein.

28. The method of claim 25, further comprising forming the enclosure via injection molding.

29. The method of claim 28, further comprising forming the base component of the package by placing the conductive bodies in a mold and forming the dielectric substrate by injection molding a plastic around the conductive bodies in the mold.

30. The method of claim 29, wherein the mold comprises two sections at least one of which defines recesses into which the conductive bodies are inserted before the plastic is injected.

31. The method of claim 30, wherein recesses in one section of the mold are conical in shape.

32. The method of claim 28, further comprising:
embedding the conductive bodies in a dielectric insert;
inserting the dielectric insert into a mold; and
injecting plastic into the mold to encase the dielectric insert and form the base component of the package.

33. The method of claim 25, further comprising inserting the conductive bodies into the dielectric substrate such that surfaces of the conductive bodies are exposed on opposite sides of the dielectric substrate.

34. The method of claim 25, further comprising forming the conductive bodies by plating electrically conductive material in orifices defined by the dielectric substrate.

35. The method of claim 25, further comprising forming the conductive bodies on a surface of the dielectric substrate and then punching the conductive bodies through the substrate such that a surface of each conductive body is exposed on a side of the dielectric substrate opposite from the side on which the conductive body was formed.

36. The method of claim 25, further comprising sealing the lid to the enclosure using one or more of the following: adhesive, heat, laser energy, and ultrasonic bonding.

37 The method of claim 36, further comprising sealing the lid using infrared or near-infrared energy, wherein the lid comprises a material that absorbs infrared or near-infrared energy photons.

38. The method of claim 25, wherein the conductive bodies are substantially spherical upon commencement of the method.

39. The method of claim 38, further comprising flattening exposed surfaces of the substantially spherical conductive bodies extending through at least one side of the dielectric substrate.

40. The method of claim 38, further comprising coining exposed surfaces of the substantially spherical conductive bodies extending through at least one side of the dielectric substrate to form flanges around the dielectric substrate at orifices through which the conductive bodies extend.

41. The method of claim 38, further comprising coining exposed surfaces of the substantially spherical conductive bodies extending through at least one side of the dielectric substrate into substantially conical shapes.

42. The method of claim 25, wherein the lid comprises conductive bodies that extend therethrough.
